(19) United States
(12) Patent Application Publication
(10) Pub. No.: US 2005/0225473 A1
(43) Pub. Date: Oct. 13, 2005

(54) INFRARED EMISSION SENSOR

(76) Inventor: Alex Hill, Aspen, CO (US)

Correspondence Address: GLENN L. WEBB, P.O BOX 951, CONIFER, CO, 80433, US

(21) Appl. No.: 10/709,047

(22) Filed: Apr. 8, 2004

(51) Int. Cl. H03M 11/00; H03K 17/94

(52) U.S. Cl. 341/176

(57) ABSTRACT

13A control keypad assembly that employs an infrared transmitter and receiver to detect the presence of a human body and control a variety of output devices. The control circuit requires that the infrared receiver and the infrared transmitter be housed in separate switch button to eliminate the false triggering caused by other heat-emitting devices and by spurious reflections. By separating the two infrared sensor components, the control circuit is only triggered when the receiver component receives a reflection from the transmitter component. This triggering allows the backlight of the control keypad assembly to illuminate the face of the keypad and the variety of buttons on its face, as well as control a variety of other output devices.

### BACKGROUND OF INVENTION

1. Field of the Invention

The present invention relates to an infrared transmission sensor for controlling inputs and outputs by detecting the presence of a users hand.

2. Background of the Invention

Most electrical and electronic devices require an activation mechanism for turning the device on and off. These activation mechanisms may be as simple as an on and off switch or more complicated requiring an input, such as an alphanumeric key code, or other types of mechanisms. Since many of these devices may operate in a dark environment, finding and operating the mechanism may be difficult. Thus, it is often desirable to have a sensing mechanism that provides illumination in order to assist in operating the activation mechanism.

A variety of sensors exist for detecting the presence of people in a room. Other sensors exist for detecting a general motion within a fixed distance from the sensor. These devices are typically coupled to a control system, which allow for certain inputs or outputs to be switched electronically upon detection by the device. One technology employed by some of these sensors involves the use of a modulated infrared transmission. This type of sensor, such as the one disclosed in U.S. Pat. No. 6,522,078, detects the heat given off by a human body. This technology relies solely on the presence of a human body to transmit infrared signals to the sensor. One disadvantage of this system is the false triggering that will occur due to the heat given off by other devices in the room.

Another system uses a dual sensor system to provide redundancy, such as the one disclosed by U.S. Pat. No. 5,189,393. Again, this system does not eliminate false triggering that may occur by the presence of a device that both moves and gives off heat, such as a dishwasher, a fan, or other electronic household devices.

Other infrared sensors operate by transmitting an infrared signal, and activate by reflection of that signal into an infrared receiver. One disadvantage of this system is that random or spurious reflections from other objects in the room may falsely trigger the system. This system also requires the use of a special lens to eliminate reflections off the housing of the transmitting and receiving devices, and result in further false triggering of the control system.

Thus, there is a present need for a sensor that is more accurately conditioned on the presence of a human body, and does not result in false triggering, and the resultant switching of control inputs and outputs unnecessarily. In particular, there is a need for a sensor that also eliminates the spurious reflections that require a special lens in order to work effectively.

### SUMMARY OF INVENTION

The present invention solves these problems and others by providing a sensing mechanism for detecting the presence of a human body. The present invention, in a preferred embodiment, provides a keypad control, infrared transmitter and infrared receiver assembly for detecting the presence of a human body to control a variety of output devices. The combination of a transmitter and receiver eliminates false triggering due to non-human heat emitting objects. The two components of the sensor assembly are housed separately, which eliminates the need for a special lens over the housing of the infrared receiver to account for spurious reflections from the infrared transmitter.

In a preferred embodiment of the invention, the sensor assembly detects the presence of a human body within 1 inch of the infrared receiver, and sends a signal to a control logic circuit within the control keypad assembly. The control circuit controls a single output or a number of outputs. In a preferred embodiment, one output includes the illuminating of an array of LEDs, which in turn illuminate the keys or buttons on the face of the control keypad assembly. In alternate embodiments, the outputs could include a number of other devices, including but not limited to room lighting, fans, and other household devices.

Another aspect of the invention includes the illuminating of an LED or LCD screen to provide the user with a command prompt, or other necessary data for the operation of the control keypad and the corresponding output devices.

Yet another aspect of the invention is the use of a timing circuit to deactivate certain output commands after a predetermined time.

These and other features of the present invention are evident from the drawings along with the detailed description of preferred embodiments. (For a fuller understanding of the nature and advantages of the invention, reference should be made to the ensuing detailed description taken in conjunction with the accompanying drawings.)

### BRIEF DESCRIPTION OF DRAWINGS

FIG. 1 is a schematic diagram showing the relationship between the sensors, control logic and the output devices according to the present invention; and

FIG. 2 is a front view of the keypad and sensor assembly according to the present invention; and

FIG. 3 is a block diagram of the keypad and sensor system according to the present invention; and

FIG. 4 is a sketch of a human hand demonstrating the means for activating the infrared receiver.

### DETAILED DESCRIPTION

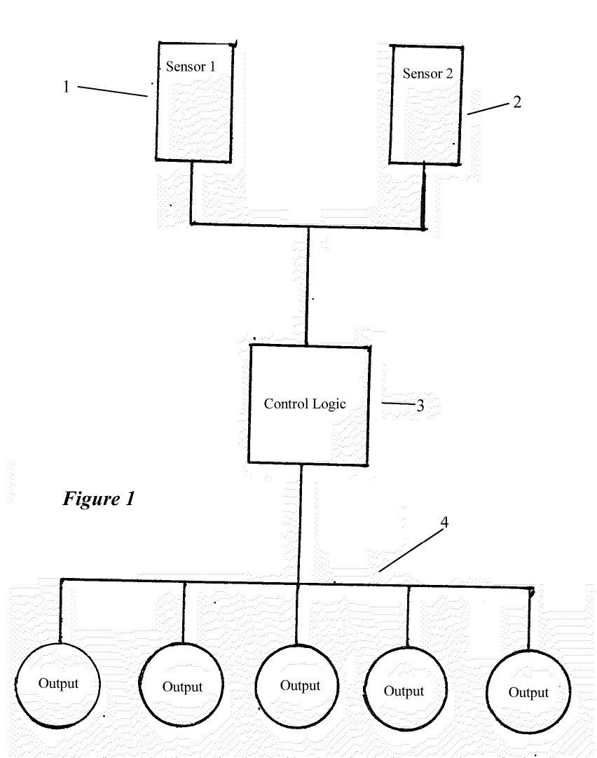

Referring in more detail to the drawings, as shown in FIGS. 1-3, a preferred embodiment of the present invention is described. It is to be expressly understood that this exemplary embodiment is provided for descriptive purposes only and is not meant to unduly limit the scope of the present inventive concept. Other embodiments, and variations of the sensors and control circuitry of the present invention are considered within the present inventive concept as set forth in the claims herein. For explanatory purposes only, the sensors and control circuitry of the preferred embodiments are discussed primarily for coupling with outputs that provide illumination. It is to be expressly understood that other output devices are contemplated for use with the present invention as well.

FIG. 1 shows a schematic diagram of the assembly of a descriptive embodiment. In one preferred embodiment, this assembly includes a transmitting sensor 1, a receiving sensor 2, a control logic circuit 3, and a plurality of output devices 4.

Referring in more detail to the drawings, as shown in FIGS. 1-3, a preferred embodiment of the present invention is described. It is to be expressly understood that this exemplary embodiment is provided for descriptive purposes only and is not meant to unduly limit the scope of the present inventive concept. Other embodiments, and variations of the sensors and control circuitry of the present invention are considered within the present inventive concept as set forth in the claims herein. For explanatory purposes only, the sensors and control circuitry of the preferred embodiments are discussed primarily for coupling with outputs that provide illumination. It is to be expressly understood that other output devices are contemplated for use with the present invention as well.

FIG. 1 shows a schematic diagram of the assembly of a descriptive embodiment. In one preferred embodiment, this assembly includes a transmitting sensor 1, a receiving sensor 2, a control logic circuit 3, and a plurality of output devices 4.

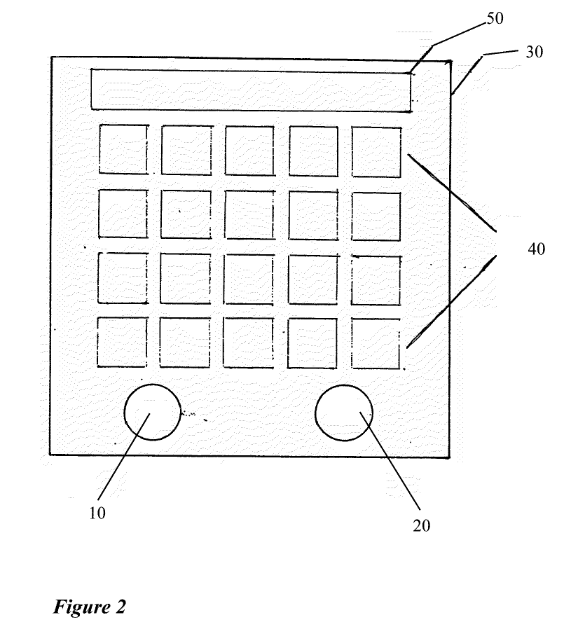

FIG. 2 shows a control keypad and infrared sensor assembly according to a preferred embodiment of the present invention. In this preferred embodiment, the assembly includes a housing 30, including an infrared transmitter 10 and an infrared receiver 20, both enclosed in a standard switch button recess. On the face of the housing 30 is an array of keys or buttons 40 which allow the user to input alphanumeric characters or select other predefined commands, which then are displayed on an LED or LCD screen 50.

In this preferred embodiment, the user may use the keys or buttons 40 on the control keypad 30 to enter a string of characters, such as a password or code, or may select a command for controlling of certain output devices. The correct sequence or command then causes activation, deactivation or other activity to control the output devices 4.

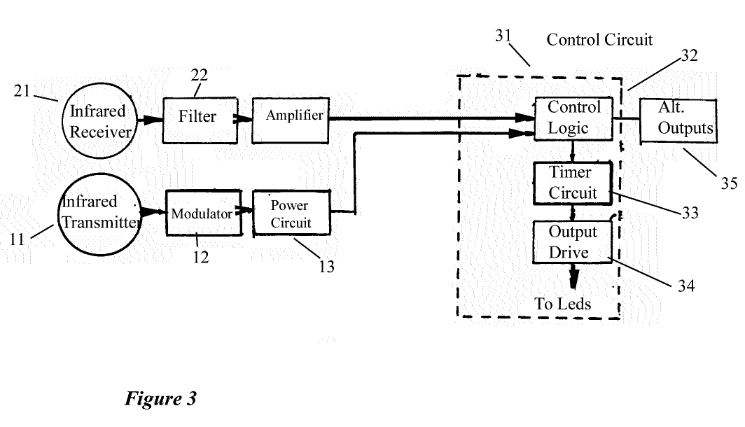

FIG. 3 is a detailed circuit diagram of one embodiment of the system in FIG. 2. A power circuit 13 and a modulator 12 provide a signal to the infrared transmitter 11. The transmitter intermittently sends a modulated infrared signal, which is not detected by the infrared receiver 21 in its steady state because they are contained in separate recesses. When a person's hand or other heat-emitting object comes within the field of the infrared transmitter 11, it will be reflected onto the infrared receiver 21. The signal then passes through a demodulator 22, a filter 23, and an amplifier 24, and then on to the control circuit 31.

Once a signal has been received by the control circuit 31, the control logic 32 provides an enabling signal to a timer circuit 33 and to an output drive circuit 34 which is coupled to the LEDs behind the face of the control keypad 30. The LEDs are arranged directly behind and congruent with the array of keys or buttons 40 so that they illuminate. The timing circuit 33 maintains the load to the LEDs for a minimal amount of time as determined by the timing circuit.

In another embodiment, the output drive circuit 34 is coupled to the LED or LCD screen 50, which will then illuminate as the user triggers the infrared receiver 21. The screen 50 may then display data to the user necessary for input of characters on the array of keys or button 40.

In the preferred embodiment, the control logic 32 will also provide enabling signals to other outputs 36 as specified by the application of the control keypad 30. The user may use the keys or buttons 40 on the control keypad 30 to enter a string of characters, such as a password or code, or may select the activation or deactivation of certain output devices.

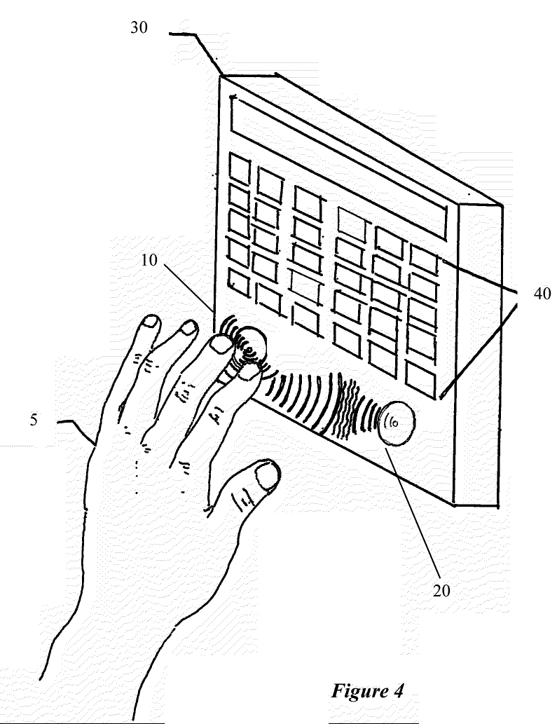

FIG. 4 is a sketch of a user's hand 5 activating the infrared receiver 20. As the infrared transmitter 10 sends a signal, any presence of a heat-emitting object such as a human body part will reflect that signal. In one preferred embodiment, only objects within a specific distance from the control keypad 30 will reflect the signal and trigger the infrared receiver 20, thereby illuminating the array of keys or buttons 40.

An example of use of the above described embodiment may be in use to deactivate an alarm system in a residence. Typically, the person entering the residence at night will enter a dark room. The person then has a set amount of time to locate the alarm keypad and enter the correct sequence of alphanumeric characters. If the person fails to enter the correct sequence of characters within the set amount of time, the alarm is triggered. This typically will set off a loud alarm and/or send a signal to a security firm or local police. The present invention will sense the presence of the person in the room, and then provide illumination to allow the person to locate the keypad and enter the correct sequence of characters to deactivate the alarm.

In another embodiment, the user may adjust the field of the infrared transmitter 10 and thereby adjust the distance from the control keypad 30 necessary to trigger the infrared receiver 20.

As will be understood by those familiar with the art, the present invention may be embodied in other specific forms without departing from the spirit or essential characteristics thereof. For example, the use of the infrared transmitter 11 and infrared receiver 21 may also be used to trigger the activation of other output devices, such as room lighting, room appliances, or other power circuitry without the presence of the array of keys or buttons 40 or the LED or LCD screen 50. The present invention is not limited in the number or type of output devices that may be controlled by activating the infrared sensor assembly. Accordingly, the disclosure of the preferred embodiment of the invention is intended to be illustrative, but not limiting, of the scope of the invention which is set forth in the following claims.

1. A motion sensor for detecting motion and providing a control signal, comprising:
at least one infrared transmitter;
at least one infrared receiver for receiving a reflected signal from said at least one infrared transmitter;
said at least one infrared transmitter contained in a first housing;
said at least one infrared receiver contained in a second housing;
said receiving a reflected signal from said at least one infrared transmitter coupled to at least one control circuit; and
said at least one control circuit controlling at least one output.

2. The motion sensor of claim 1 further comprising:
means for employing an intermittently transmitted infrared signal from said at least one infrared transmitter, for reception of a reflection of said intermittently transmitted infrared signal by said at least one infrared receiver, and for communication of said reflection to said at least one control circuit.

3. The motion sensor of claim 2 where said means further includes:
means for detecting an infrared reflection within a predetermined distance from said at least one transmitter.

4. The motion sensor of claim 2 where said means further includes:
means for illuminating a device by activating said at least one output.

5. The motion sensor of claim 2 where said means further includes:
means for initiating a timing device by activating said at least one output.

6. The motion sensor of claim 2 where said means further includes:
means for changing the status a device by activating said at least one output.

7. A control keypad configuration, said keypad configuration comprising:
at least one control circuit for controlling at least one output device;
at least one button on said control keypad configuration;
said at least one button including a LED for illuminating the surface of said at least one button;
at least one infrared transmitter located adjacent to said control keypad configuration;
at least one infrared receiver for receiving a reflected signal from said at least one infrared transmitter;
said at least one infrared transmitter contained in a first housing;
said at least one infrared receiver contained in a second housing;
a receiving mechanism receiving a reflected signal from said at least one infrared transmitter;
said receiving mechanism coupled to said at least one control circuit; and
an illumination mechanism illuminating said at least one button upon said receiving a reflected signal from said at least one infrared transmitter.

8. The control keypad assembly of claim 7 further comprising:
a first mechanism employing an intermittently transmitted infrared signal from said at least one infrared transmitter,
a second mechanism receiving a reflection of said intermittently transmitted infrared signal by said at least one infrared receiver, and
a third mechanism communicating said reflection to said at least one control circuit.

9. The control keypad assembly of claim 8 where said key pad assembly further includes:
a detection mechanism detecting an infrared reflection within a predetermined distance from said at least one transmitter.

10. The control keypad assembly of claim 8 where said keypad assembly includes:
a timing mechanism initiating a timing device by activating said at least one output.

11. The control keypad assembly of claim 8 where said keypad assembly includes:
a control mechanism changing the status a device by activating said at least one output.

12. A method for detecting the presence of a human body, comprising:
at least one infrared transmitter;
at least one infrared receiver for receiving a reflected signal from said at least one infrared transmitter;
said at least one infrared transmitter contained in a first housing;
said at least one infrared receiver contained in a second housing;
at least one control circuit coupled to said at least one infrared receiver;
said detecting the presence of a human body occurring when a reflection from said infrared transmitter is received by said infrared receiver; and
said control circuit coupled to at least one output device for controlling the status of said at least one output device.

13. The method of claim 12 further comprises:
employing an intermittently transmitted infrared signal from said at least one infrared transmitter,
receiving a reflection of said intermittently transmitted infrared signal by said at least one infrared receiver, and
communicating said reflection to said at least one control circuit.

14. The method of claim 13 further comprising:
detecting an infrared reflection within a predetermined distance from said at least one transmitter.

15. The method of claim 13 wherein said method further includes:
illuminating a device by activating said at least one output.

16. The method of claim 13 where said method further includes:
initiating a timing device by activating said at least one output.

17. The method of claim 13 where said method further includes:
changing the status a device by activating said at least one output.
